(19) United States
(12) Patent Application Publication
(10) Pub. No.: US 2006/0154394 A1
(43) Pub. Date: Jul. 13, 2006

(54) Plasma display panel and manufacturing method of the same

(75) Inventors: Toshiyuki Nanto, Miyazaki (JP); Hideki Harada, Miyazaki (JP)

Correspondence Address: STAAS & HALSEY LLP, SUITE 700, 1201 NEW YORK AVENUE, N.W., WASHINGTON, DC, 20005, US

(73) Assignee: Fujitsu Hitachi Plasma Display Limited, Kawasaki (JP)

(21) Appl. No.: 11/327,318

(22) Filed: Jan. 9, 2006

(30) Foreign Application Priority Data
Jan. 13, 2005 (JP) 2005-006626

(51) Int. Cl. H01L 21/4763; H01L 21/00

(52) U.S. Cl. 438/26; 438/622

(57) ABSTRACT

The manufacturing method includes the step of forming a dielectric layer on a substrate where electrodes are formed so as to coat the electrodes in accordance with a vapor phase growth method, the step of carrying out a process for planarization on the dielectric layer, and the step of forming a protective film on the dielectric layer.

### CROSS-REFERENCE TO RELATED APPLICATION

This application is related to Japanese Patent Application No. 2005-006626 filed on Jan. 13, 2005, on the basis of which priority is claimed under 35 USC § 119, the disclosure of this application being incorporated by reference in its entirety.

### BACKGROUND OF THE INVENTION

1. Field of the Invention

The present invention relates to a plasma display panel (hereinafter referred to as “PDP”) and a manufacturing method of the same, and in particular, to a PDP where reduction in display irregularity is achieved, and a manufacturing method of the same.

2. Description of the Related Art

AC type three-electrode surface discharge style PDPs are known as PDPs. In an example of this widely used type of PDP, a great number of display electrodes where surface discharge is possible are provided on the inner surface of a substrate on the front side (display surface side) in the lateral direction, and a great number of address electrodes for selecting light emitting cells are provided on the inner surface of a substrate on the rear side in the direction crossing the display electrodes, so that the intersecting portions between the display electrodes and address electrodes can be used as cells.

The display electrodes are coated with a dielectric layer, and a protective film is formed on top of this. The address electrodes are also coated with a dielectric layer, partitions are formed between the address electrodes, and fluorescent layers are formed between the partitions.

PDPs are fabricated by making a panel assembly on the front side that has been fabricated as described above and a panel assembly on the rear side face each other and sealing the periphery, and after that, introducing a discharge gas inside.

When the substrate on the front side of such a PDP is viewed, the display electrodes are coated with a dielectric layer, and a protective film is formed on top of this. In general, as the dielectric layer, a low melt point glass layer having a thickness of no less than 10 μm is formed in a process for forming a thick film, and in many cases, the protective film is formed in a process for forming a thin film of which the thickness is approximately 1 μm.

In recent years, however, a dielectric layer having a low dielectric constant has been in demand, in order to save energy, and therefore, as the dielectric layer, SiO₂ films have been formed in accordance with a vapor phase growth method.

In the case where a dielectric layer is formed in accordance with a vapor phase growth method, the surface of the dielectric layer follows the form of the base, which is, for example, electrodes. As a result, the surface of the dielectric layer becomes uneven (see Japanese Unexamined Patent Publication 2000-21304). In particular, in the case where the base includes electrodes or the like having a great film thickness, the surface of these electrodes causes a high degree of unevenness, and thus, the surface of the dielectric layer also becomes highly uneven.

In the case where the surface of the dielectric layer is highly uneven in this manner, the surface area of the protective film that is formed on top of the dielectric layer increases, making it easy for the discharge gas that has been introduced inside the PDP to be absorbed by the protective film. Therefore, the voltage for discharging increases, due to an increase in the amount of the discharge gas absorbed by the protective film. In particular, in the case where the unevenness or difference in level in the surface form of the base has a radius of curvature which is of the same level as the thickness of the protective film, gaps are created between the crystals of the protective film, causing a further increase in the surface area.

In addition, in the case where the surface of the substrate has such unevenness, the portion of the substrate that makes contact with partitions becomes uneven, in a panel structure where such partitions are provided on the facing substrate, and therefore, the load is concentrated, causing chipping in the partitions.

The present invention is provided taking this situation into consideration, and according to the present invention, a process for planarization is carried out on the dielectric layer that coats the display electrodes, and thereby, the dielectric layer is planarized, which, in turn, makes the protective film that is formed on the dielectric layer planarized, and thus, the voltage for discharging is made uniform between the display electrodes.

### SUMMARY OF THE INVENTION

The present invention provides a manufacturing method for an AC type plasma display panel which is formed by coating electrodes that are provided on a substrate with a dielectric layer, and the manufacturing method for a plasma display panel is provided with the steps of forming a dielectric layer in accordance with a vapor phase growth method on a substrate where electrodes are formed, in such a manner that these electrodes are coated with the dielectric layer, and forming a protective film on top of this dielectric layer, and is characterized in that the step of carrying out a process for planarization on the dielectric layer is provided.

According to the present invention, a dielectric layer is planarized, and thereby, the protective film is also planarized, and thereby, the amount of discharging gas absorbed by the protective film can be reduced, and the voltage for discharging can be made uniform between the display electrodes. In addition, chipping of the partitions can be prevented.

### BRIEF DESCRIPTION OF THE DRAWINGS

FIGS. 1(a) and 1(b) are exploded perspective diagrams showing the configuration of a portion of a PDP which is made in accordance with a manufacturing method of the present invention;

FIG. 2 is a diagram showing an example of planarization of a dielectric layer;

FIGS. 3(a) to 3(f) are diagrams showing an example of a method of planarizing the dielectric layer;

FIG. 4 is a diagram showing an example of planarization of a metal electrode;

FIGS. 5(a) to 5(d) are diagrams showing an example of a method of planarizing the metal electrode;

FIG. 6 is a diagram showing an example of planarization of the edges of an electrode;

FIGS. 7(a) and 7(b) are diagrams showing an example of a method of planarizing the edges of the electrode;

FIGS. 8(a) and 8(b) are diagrams showing another example of the method for planarizing the edges of the electrode;

FIG. 9 is a diagram showing an example of planarization of the edges of a layered electrode;

FIGS. 10(a) to 10(f) are diagrams showing an example of a method of planarizing the edges of the layered electrode:

FIGS. 11(a) to 11(e) are diagrams showing an example of a method of planarizing the edges of a two-layered electrode;

FIG. 12 shows a comparison example where no planarization is carried out on the dielectric layer; and

FIG. 13 shows a comparison example where no planarization is carried out on the thick film electrode

### DESCRIPTION OF THE PREFERRED EMBODIMENTS

In the present invention, a panel assembly on the front side and a panel assembly on the rear side include substrates on the front side and on the rear side, respectively, made of glass, crystal, ceramics or the like, where a desired structure is formed of electrodes, an insulating film, a dielectric layer, a protective film and the like.

The electrodes can be formed on the substrate on the front side of any of a variety of materials in accordance with a method which are known in the art. As the material used for the electrodes, transparent conductive materials, such as ITO and SnO₂, and conductive materials of metals such as Ag, Au, Al, Cu and Cr, for example, can be cited. As the method for forming electrodes, any of a variety of methods which are known in the art can be applied. For example, a technology for forming a thick film (process for forming a thick film), such as printing, may be used for the formation, or a technology for forming a thin film (process for forming a thin film), including a physical deposition method or a chemical deposition method, may be used for the formation. As the technology for forming a thick film, a screen printing method and the like can be cited. As the physical deposition method, from among the technology for forming a thin film, a vapor phase growth method or a sputtering method can be cited. As the chemical deposition method, a thermal CVD method, an optical CVD method and a plasma CVD method can be cited.

The dielectric layer is formed so as to coat the electrodes in accordance with a vapor phase growth method. This dielectric layer can be formed of any of-a variety of materials which are known in the art. For example, an SiO₂ film that has been formed in accordance with a vapor phase growth method can be applied. As the vapor phase growth method, a thermal CVD method and an optical CVD method, as described above, as well as a variety of chemical deposition methods, such as a plasma CVD method, can be used.

The protective film may be formed on the dielectric layer. This protective film can be formed in a process for forming a thin film which is known in the art, such as an electron beam vapor phase growth method or a plasma CVD method. It is desirable for this protective film to be formed from MgO in a process for forming a thin film of which the average film thickness is approximately 1 μm.

According to the present invention, a process for planarization is carried out on the dielectric layer. As this process for planarization, the step of forming a planarized layer on a substrate where electrodes are formed in accordance with a thick film method, using a low melt point glass paste, for example, may be applied before the formation of the dielectric layer.

In the case where the electrodes are formed on a substrate in a process for forming a thick film, as the above described process for planarization, the step of planarizing the electrodes by applying pressure on these electrodes which have been formed in the process for forming a thick film may be applied.

The above described process for planarization includes the step of removing edge portions of the electrodes before the formation of a dielectric layer. In this case, in the step of removing edge portions of the electrodes, the edges of the electrodes may be shaved in accordance with a sputter etching method after the formation of the electrodes. In addition, when the electrodes are formed through wet etching, the period of time for etching is set somewhat long, so that the edges of the electrodes can be shaved through over etching.

The present invention also provides an AC type plasma display panel where a discharging space is formed between a substrate on the front side and a substrate on the rear side, and a dielectric layer that coats electrodes, as well as a protective film that coats this dielectric layer, are provided on the inner surface of the substrate on the front side, and this plasma display panel is characterized in that at least one layer that is a portion of the dielectric layer is formed in accordance with a vapor phase growth method, and this dielectric layer is approximately planarized along the plane of the substrate, irrespectively of unevenness in the electrodes in the lower layer.

In the above described configuration, the dielectric layer can be formed of an SiO₂ film.

In the following, the present invention is described in detail on the basis of the embodiments shown in the drawings. Here, the present invention is not limited to this, but rather, a variety of modifications are possible.

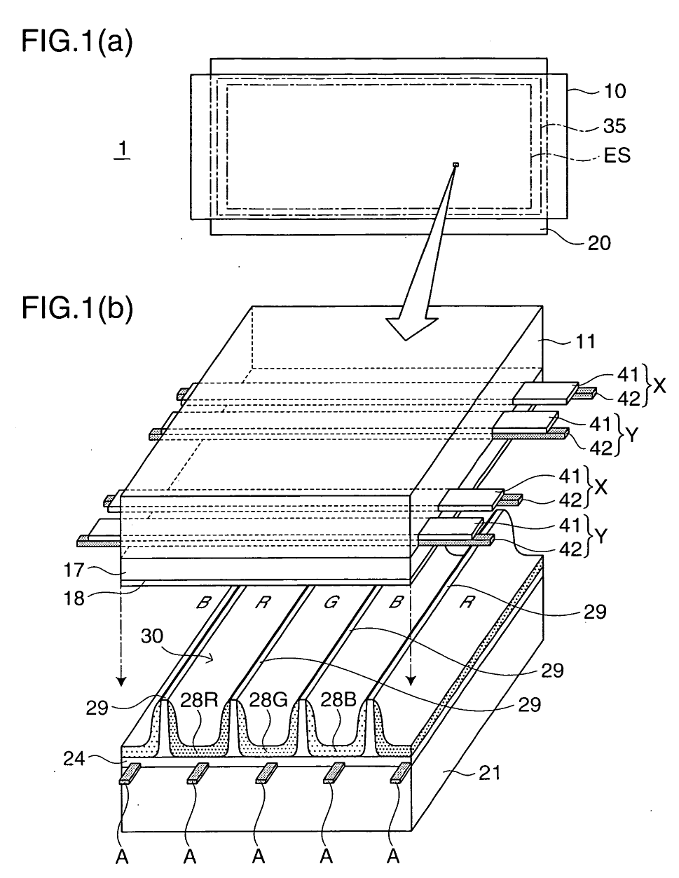

FIGS. 1(a) and 1(b) are exploded perspective diagrams showing the structure of a portion of a PDP which is made in accordance with a manufacturing method of the present invention. This PDP is an AC type three-electrode surface discharge style PDP for color display.

A PDP 1 is formed of a panel assembly 10 on the front side that includes a substrate 11 on the front side, and a panel assembly 20 on the rear side that includes a substrate 21 on the rear side. As the substrate 11 on the front side and the substrate 21 on the rear side, glass substrates, crystal substrates, ceramic substrates and the like can be used. A sealing region 35 is formed of a sealing material around the peripheral portion between the panel assembly 10 on the front side and the panel assembly 20 on the rear side, and the inside of this sealing region 35 is used as a display region ES.

On the inner surface of the substrate 11 on the front side, pairs of display electrodes X and Y are formed in the lateral direction at intervals which can prevent discharge from occurring between the pairs of electrodes. The spaces between the display electrodes X and the display electrodes Y are used as display lines L. Each of the display electrodes X and Y is formed of a transparent electrode 41 having a great width, such as ITO or SnO₂, and a metal electrode 42 having a small width made of, for example, Ag, Au, Al, Cu, Cr or a layered body of these (for example, a layered film such as Cr/Cu/Cr). Thus provided metal electrodes are generally referred to as bus electrodes. A desired number of display electrodes X and Y having a desired thickness, width and intervals can be formed using a technology for forming a thick film, such as screen printing, for Ag and Au, and using a technology for forming a thin film, such as a vapor phase growth method or a sputtering method, as well as an etching technology, for other materials.

A dielectric layer 17 for driving an alternating current (AC) is formed on the display electrodes X and Y so as to coat the display electrodes X and Y. The dielectric layer 17 is formed by growing an SiO₂ film in accordance with a vapor phase growth method.

A protective film 18 for protecting the dielectric layer 17 from being damaged due to the collision of ions caused by the discharge at the time of displaying is formed on the dielectric layer 17. This protective film is formed of MgO.

A number of address electrodes A are formed on the inner surface of the substrate 21 on the rear side in the direction crossing the display electrodes X and Y as seen in a plan view, and a dielectric layer 24 is formed so as to coat these address electrodes A. The address electrodes A generate address discharge for selecting luminescent cells at intersecting portions vis-a-vis the Y electrodes, which are one electrode from the pairs of electrodes, and are formed so as to have a three-layered structure of Cr/Cu/Cr. These address electrodes A can also be formed of other materials, such as, for example, Ag, Au, Al, Cu or Cr. A desired number of address electrodes A having a desired thickness, width and intervals can be formed in the same manner as the display electrodes X and Y, using a technology for forming a thick film, such as screen printing, for Ag and Au, and using a technology for forming a thin film, such as a vapor phase growth method or a sputtering method, as well as an etching technology, for other materials. The dielectric layer 24 is formed by applying a low melt point glass paste to the substrate 21 on the rear side in accordance with a screen printing method and baking this.

A number of partitions 29 are formed on the dielectric layer 24 between the adjacent address electrodes A. The partitions 29 can be formed in accordance with a sandblast method, a printing method, a photo etching method or the like. In the case of a sandblast method, for example, a glass paste made of a low melt point glass frit, a binder resin and a solvent is applied to the dielectric layer 24 and dried, and after that, cutting particles are blasted in a state where a cutting mask having a partition pattern with openings is provided on this glass paste layer, and thereby, the glass paste layer that is exposed from the openings of the mask is cut, and in addition, baked, and thereby, the partitions are formed. In addition, in the case of a photo etching method, a photosensitive resin is used as the binder resin, and the glass paste is exposed to light using a mask and developed instead of cut with cutting particles, and after that, the glass paste is baked, and thereby, the partitions are formed.

Fluorescent layers 28R, 28G and 28B for red (R), green (G) and blue (B) are formed on the sides of the partitions 29 and on the dielectric layer 24 between the partitions. A fluorescent paste that includes fluorescent powder, a binder resin and a solvent is applied to the inside of discharge spaces in trench form between the partitions 29 in accordance with screen printing or a method using a dispenser, and this is repeated for each color, and after that, the fluorescent paste is baked, and thereby, the fluorescent layers 28R, 28G and 28B are formed. These fluorescent layers 28R, 28G and 28B can be formed in accordance with a photolithographic technology using a fluorescent layer material in sheet form (so-called green sheet) that includes fluorescent powder, a photosensitive material and a binder resin. In this case, a sheet of a desired color is pasted to the entire surface of the display region on the substrate, and then, exposed to light and developed, and this is repeated for each color, and thereby, the fluorescent layers of each color can be formed in the corresponding spaces between the partitions.

The above described panel assembly on the front side and panel assembly on the rear side are placed so as to face each other in such a manner that the display electrodes X and Y and the address electrodes A cross each other, the periphery is sealed with a sealing material, and discharge spaces 30 that is surrounded by the partitions 29 are filled in with a discharge gas, and thereby, a PDP is fabricated. In this PDP, each discharge space 30 at an intersecting portion of display electrodes X and Y and an address electrode A becomes one cell region, which is a minimum unit for display (unit light emitting region). One pixel is formed of three cells of R, G and B.

A process for planarization is carried out beneath the dielectric layer 17, which characterizes the present invention, and this process for planarization is described using the following embodiments.

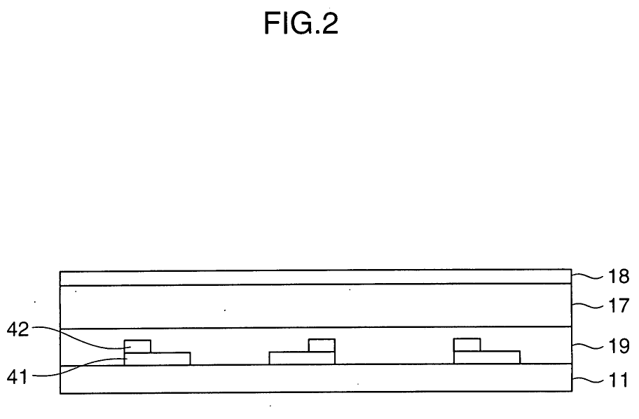

FIG. 2 is a diagram illustrating an example of planarization of a dielectric layer.

Transparent electrodes 41 and metal electrodes 42 are formed as display electrodes X and Y on a substrate 11 on the front side. The transparent electrodes 41 are electrodes made of ITO, and metal electrodes 42 are metal electrodes made of a three-layered film of Cr/Cu/Cr. These metal electrodes 42 may be formed of Ag, Au or the like in accordance with a thick film method, such as screen printing.

When transparent electrodes 41 and metal electrodes 42 are formed on a substrate 11 on the front side in this manner, and a dielectric layer 17 is formed directly on top of this in accordance with a vapor phase growth method, the surface of the dielectric layer 17 does not become flat. In order to solve this problem, a planarized layer 19 is formed beneath the dielectric layer 17, and thereby, the dielectric layer 17 is planarized in accordance with the present embodiment.

That is to say, a planarized layer 19 is formed on the transparent electrodes 41 and the metal electrodes 42, and a dielectric layer 17 made of an SiO₂ film is formed on top of this planarized layer 19 in accordance with a vapor phase growth method, and then, a protective film 18 is formed on top of this dielectric layer 17.

The unevenness of the transparent electrodes 41 and the metal electrodes 42 is planarized by the planarized layer 19, and a dielectric layer 17 is formed on top of this, and therefore, the dielectric layer 17 is planarized. In addition, a protective film 18 is formed on this planarized dielectric layer 17, and therefore, the protective film 18 is formed flat.

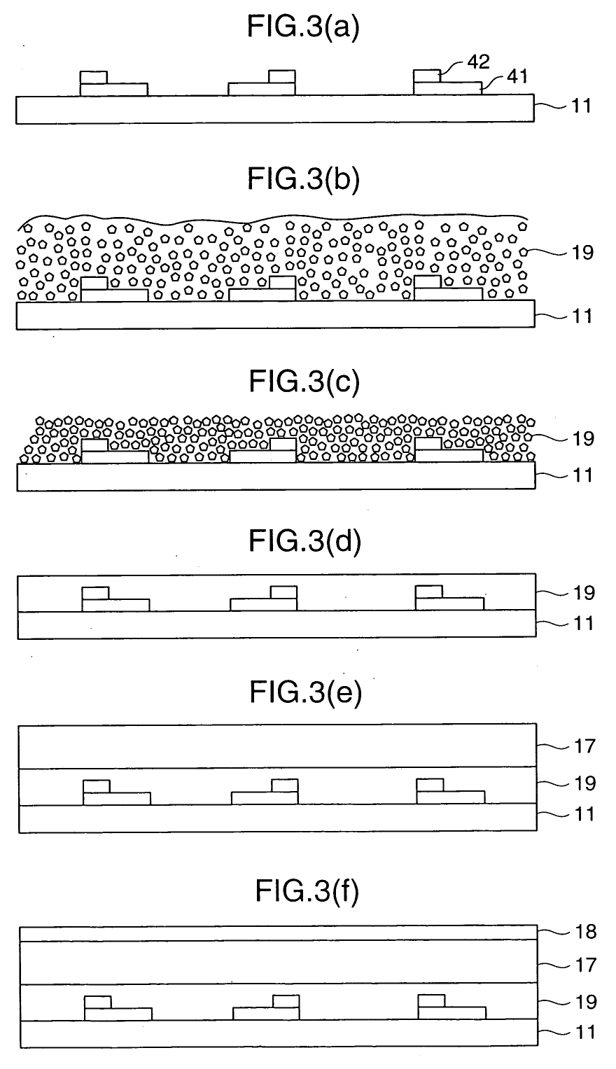

FIGS. 3(a) to 3(f) are diagrams illustrating one example of a method for planarizing a dielectric layer.

First, transparent electrodes 41 and metal electrodes 42 are formed on a substrate 11 on the front side in accordance with a thin film method (method for processing a thin film) or a thick film method (method for processing a thick film) (see FIG. 3(a)).

Next, a planarized layer 19 of which the surface is planarized through leveling is formed. This planarized layer 19 is formed by coating the transparent electrodes 41 and the metal electrodes 42 with a paste made of a low melt point glass, a binder resin and a solvent in accordance with a technique such as screen printing (see FIG. 3(b)).

After that, the solvent is vaporized in the step of drying (150° C. to 250° C.) (see FIG. 3(c)), and the binder resin is burned off in the step of baking (500° C. to 600° C.),and the low melt point glass is fused and solidified, and thereby, the planarized layer 19 is formed (see FIG. 3(d)).

At this time, the surface of the layer is planarized as a result of leveling effects in the step of drying and the step of baking. In order to provide sufficient planarization, it is desirable for the thickness of planarized layer 19 to be 3 times or more the thickness of the transparent electrodes 41 and the metal electrodes 42. A low melt point glass that has been processed into a green sheet may be pasted through lamination, instead of a low melt point glass paste being pasted.

Next, a dielectric layer 17 is formed on top of the planarized layer 19 in accordance with a thin film method (see FIG. 3(e)). Here, the dielectric layer 17 is formed of an SiO₂ film having a thickness of approximately 1 μm in accordance with a vapor phase growth method.

Finally, a protective film 18 is formed on top of the dielectric layer 17 in accordance with a thin film method (see FIG. 3(f)). Here, the protective film 18 is formed of an MgO film having a thickness of approximately 5000 Å in accordance with a vapor deposition method.

The dielectric layer 17 is planarized, and thereby, the protective film 18 is planarized, so that the amount of gas absorbed by the protective film 18 can be prevented from increasing. In addition, chipping of the partitions can be prevented.

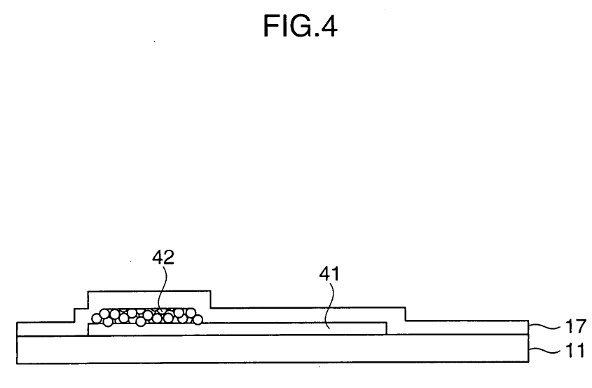

FIG. 4 is a diagram illustrating an example of planarization of a metal electrode.

In the case where a transparent electrode 41 is formed on top of a substrate 11 on the front surface, and after that, a metal electrode 42 is formed of Ag, Au or the like in accordance with a thick film method, the metal electrode 42 is not formed flat. In the present embodiment, in order to solve this problem the metal electrode 42 is pressed so as to be planarized, and a dielectric layer 17 is formed on top of this, and thereby, the dielectric layer 17 is planarized.

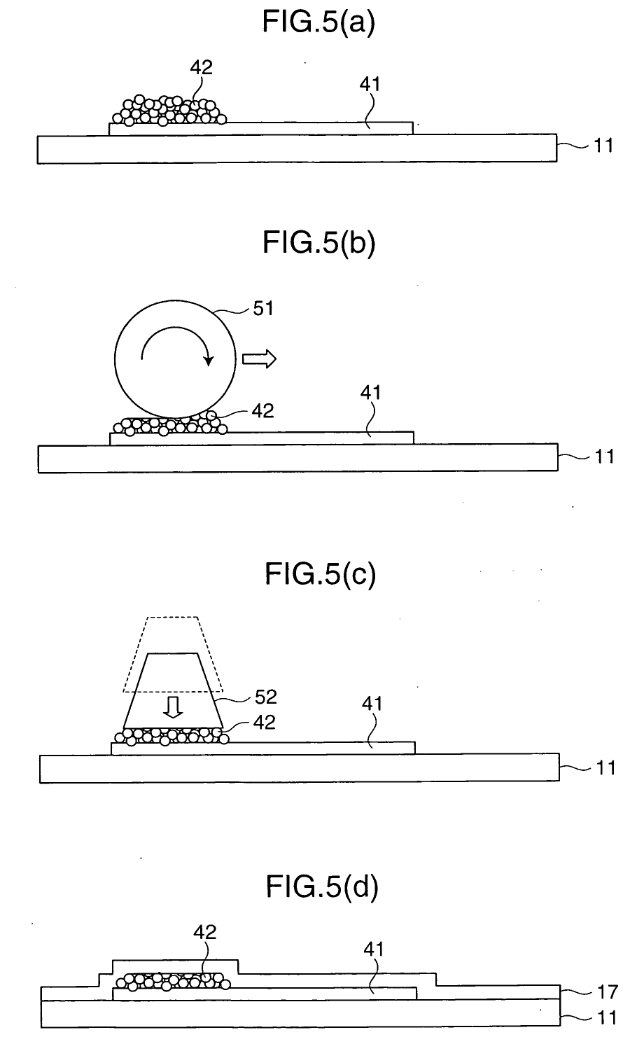

FIGS. 5(a) to 5(d) are diagrams illustrating an example of a method for planarizing a metal electrode.

First, a transparent electrode 41 is formed on top of a substrate 11 on the front side in accordance with a thin film method, and a metal electrode 42 is formed on top of this transparent electrode 41 in accordance with a thick film method (see FIG. 5(a)).

In the case where the metal electrode 42 is formed in accordance with a thick film method, metal particles are on a level where the diameter is several microns, and the surface is highly uneven. Therefore, the surface of the metal electrode 42, which is a thick film, is polished with a sheet for polishing or the like. Alternatively, the metal electrode 42, which is a thick film, may be pressed a roller 51 (see FIG. 5(b)). Alternatively, the metal electrode 42 which is a thick film may be deformed through pressing with a presser 52, so that the surface is planarized.

After that, a dielectric layer 17 is formed in accordance with a vapor phase growth method (see FIG. 5(d)), and a protective film is formed on top of this.

In this case, a material having microscopic particles on a level where the diameter is several nanometers is used for the formation of the metal electrode, and thereby, the degree of planarization of the surface of the metal may be improved.

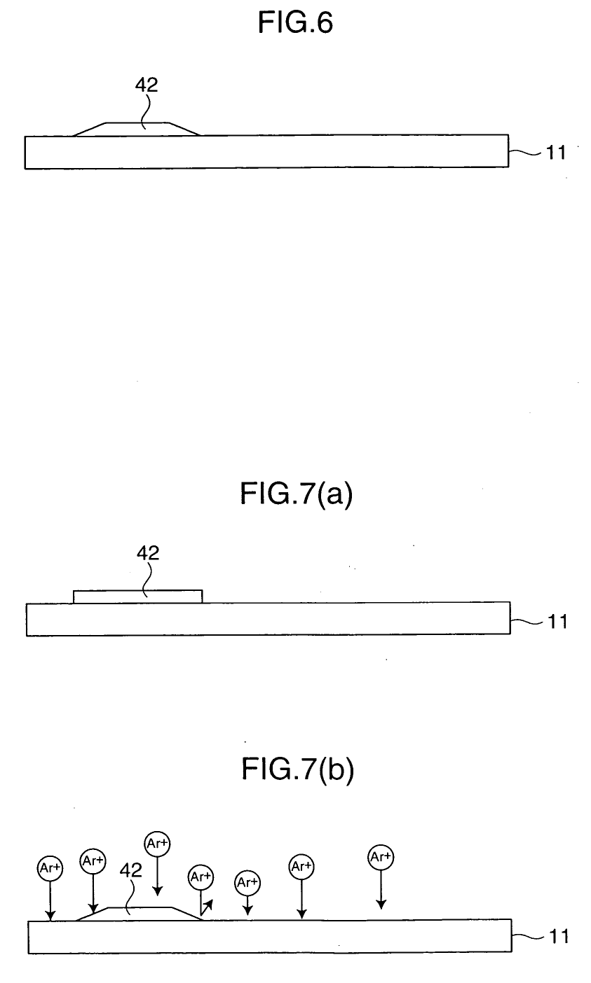

FIG. 6 is a diagram illustrating an example of planarization of the edges of an electrode.

In the present embodiment, the edges of the metal electrode that has been formed in accordance with a thin film method are inclined, and thereby, the dielectric layer is planarized.

FIGS. 7(a) and 7(b) are diagrams illustrating an example of a method for planarizing the edges of an electrode.

First, a metal electrode film is formed on the entirety of a substrate 11 on the front side, and a resist is patterned in accordance with a photolithographic method, and a metal electrode 42 is formed through wet etching (see FIG. 7(a)).

Next, the edges of the metal electrode 42 are shaved in accordance with a sputter etching method (see FIG. 7(b)). In the present embodiment, an example where ion sputter etching is carried out using Ar ions is shown.

Alternatively, the metal electrode 42 may be mechanically polished with a polishing cloth or the like.

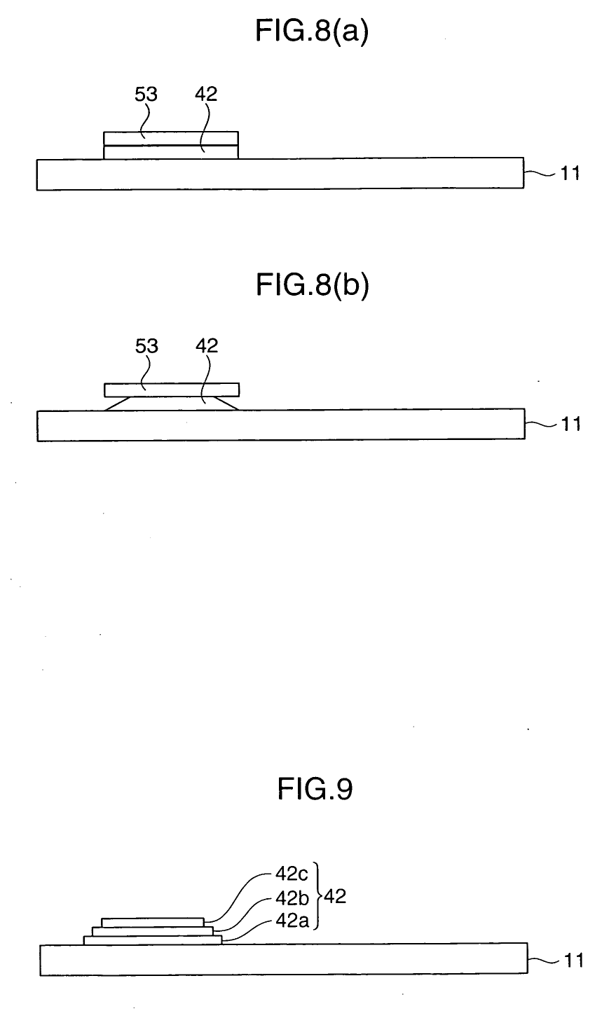

FIGS. 8(a) and 8(b) are diagrams illustrating another example of a method for planarizing the edges of an electrode.

First, a metal electrode film is formed on the entirety of a substrate 11 on the front side. Next, a resist 53 is patterned in accordance with a photolithographic method. Then, in contrast to a normal case, where an appropriate period of time for etching is set so that etching finishes immediately after completion, as shown in FIG. 8(a), the period of time for etching is intentionally set longer, so that over etching occurs in the present embodiment, as shown in FIG. 8(b). As a result of this, the edges of the metal electrode 42 are inclined.

FIG. 9 is a diagram illustrating an example of planarization of the edges of a layered electrode.

In the present embodiment, in the case of a metal electrode where a number of layers are layered in accordance with a thin film method, the provided form is such that the width of the electrodes in upper layers becomes smaller than that of the electrodes in lower layers (pyramid form).

In the present embodiment, the first layer of the metal electrode 42 is a Cr layer 42a, the second layer is a Cu layer 42b, and the third layer is a Cr layer 42c. The layered electrode is formed with inclinations in this manner, and thereby, the dielectric layer and the protective film on top of this are planarized.

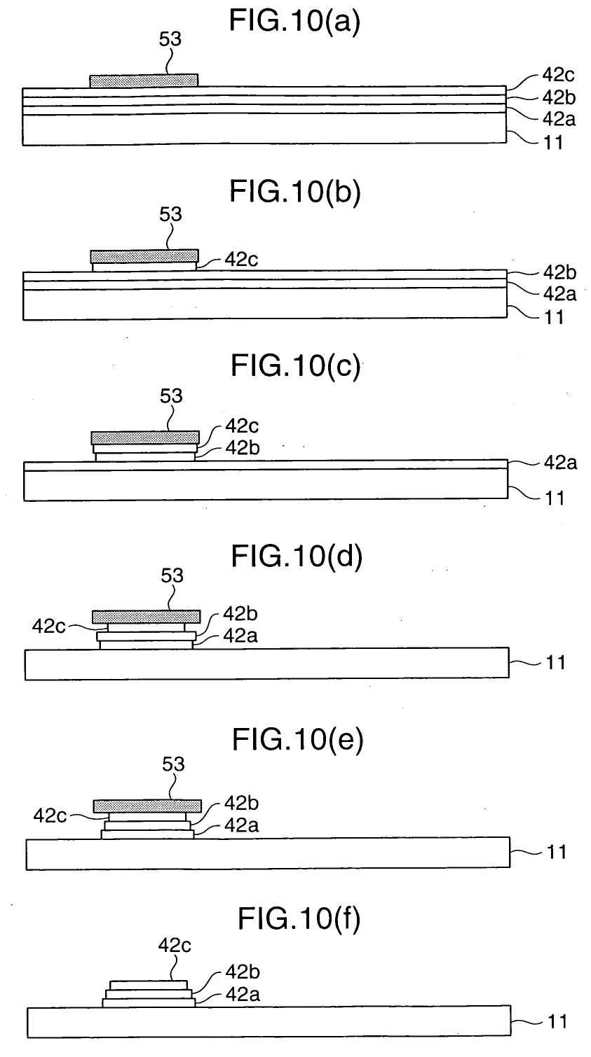

FIGS. 10(a) to 10(f) are diagrams illustrating an example of a method for planarizing the edges of a layered electrode.

First, a three-layered metal electrode film is formed on the entirety of a substrate 11 on the front side. The first layer is a Cr layer 42a, the second layer is a Cu layer 42b, and the third layer is a Cr layer 42c.

Next, a resist 53 is patterned in accordance with a photolithographic method 8 (see FIG. 10(a)). After that, an etchant for Cr is used, and wet etching is carried out on the Cr layer 42c, which is the third layer (see FIG. 10(b)). The Cr layer 42c becomes slightly narrower than the width of the resist 53.

Next, an etchant for Cu is used, and wet etching is carried out on the Cu layer 42b, which is the second layer (see FIG. 10(c)). The Cu layer 42b becomes slightly narrower than the width of the Cr layer 42c.

Next, an etchant for Cr is used, and wet etching is carried out on the Cr layer 42a, which is the first layer (see FIG. 10(d)). At the same time, the Cr layer 42c in the upper layer is etched.

Next, the etchant for Cu is used again, and wet etching is carried out on the Cu layer 42b, which is the second layer (see FIG. 10(e)). This etching is carried out for a short period of time.

Finally, the resist 53 is removed (see FIG. 10(f). As a result of this, the three-layered metal electrode 42 is formed so as to have a pyramid form, and thus, the dielectric layer and the protective film on top of this are planarized.

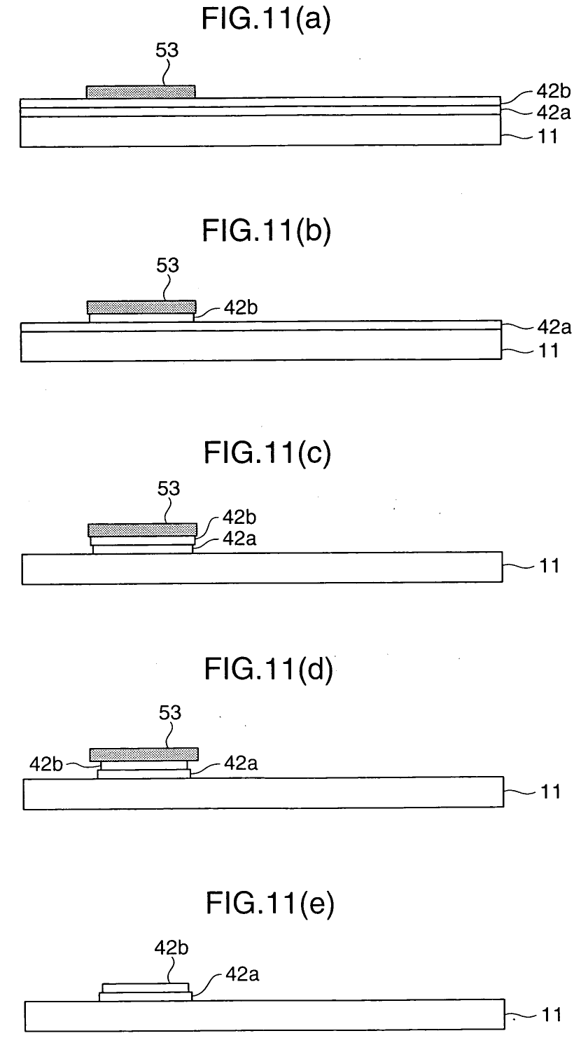

FIGS. 11(a) to 11(e) are diagrams illustrating an example of a method for planarizing the edges of a two-layered electrode.

Though the metal electrode is essentially a single layer of Cu, having a single layer of Cu may cause a problem with the connection to the substrate, or a problem of corrosion at the time of the formation of a dielectric layer, which is a thick film, as an upper layer, and therefore, in order to prevent this, a three-layered structure of Cr/Cu/Cr as that described above is provided. In the case where an SiO₂ film is formed as an upper layer of the metal electrode, however, there is no problem of corrosion, and therefore, it is not necessary to form a Cr layer as the third layer.

The present embodiment is a method for planarizing the edges of a two-layered metal electrode that has been formed as described above.

First, a two-layered metal electrode film is formed on the entirety of a substrate 11 on the front side. The first layer is a Cr layer 42a and the second layer is a Cu layer 42b.

Next, a resist 53 is patterned in accordance with a photolithographic method (see FIG. 11(a)). After that, an etchant for Cu is used, and wet etching is carried out on the Cu layer 42b, which is the second layer (see FIG. 11(b)).

Next, an etchant for Cr is used, and wet etching is carried out on the Cr layer 42a, which is the first layer (see FIG. 11(c)).

Next, the etchant for Cu is used again, and wet etching is carried out on the Cu layer 42b, which is the second layer (see FIG. 11(d)). This etching is carried out for a short period of time.

Finally, the resist 53 is removed (see FIG. 11(e)). As a result of this, the two-layered metal electrode 42 is formed so as to have a pyramid form, and thus, the dielectric layer and the protective film on top of this are planarized.

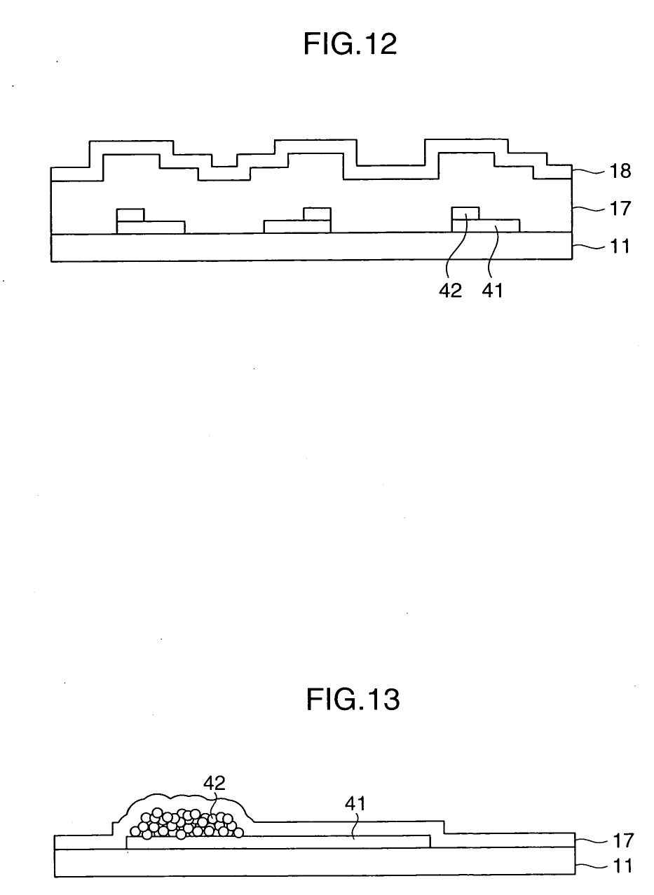

FIGS. 12 and 13 show comparison examples.

FIG. 12 shows an example where a protective film 18 is formed without carrying out planarization on the dielectric layer 17. When the protective film 18 is formed on top of the dielectric layer 17 without carrying out planarization on the dielectric layer 17, the protective film 18 has a form which follows the unevenness of the dielectric layer 17, and therefore, the surface area of the protective film 18 increases, and it becomes easy for the discharge gas that is introduced inside the PDP to be absorbed by the protective film 18. Therefore, the voltage for discharging increases, due to the increase in the amount of the discharge gas absorbed by the protective film. In addition, the portion that makes contact with the partitions that are formed on the substrate on the rear side becomes uneven, and therefore, the load is concentrated on the protruding portions, causing chipping in the partitions.

FIG. 13 shows an example where a dielectric layer 17 is formed without carrying out a process for planarizing the thick film electrode. In this case, in the same manner as in the above described case, the dielectric layer 17 becomes uneven, and when a protective film 18 is formed on top of this dielectric layer 17, the surface area of the protective film 18 increases, and it becomes easy for the discharge gas that is introduced inside the PDP to be absorbed by the protective film 18. In addition, the portion that makes contact with the partitions that are formed on the substrate on the rear side becomes uneven, and therefore, the load is concentrated, causing chipping in the partitions.

What is claimed is:

1. A manufacturing method for an AC type plasma display panel, where electrodes provided on a substrate are coated with a dielectric layer, comprising the steps of:
forming a dielectric layer on a substrate where electrodes are formed so as to coat the electrodes in accordance with a vapor phase growth method;
carrying out a process for planarization on the dielectric layer; and
forming a protective film on the dielectric layer.

2. The manufacturing method according to claim 1, wherein the dielectric layer is made of an SiO₂ film.

3. The manufacturing method according to claim 1, wherein the step of carrying out a process for planarization on the dielectric layer comprises the formation of a planarized layer in accordance with a thick film method using a low melt point glass paste on the substrate where the electrodes are formed before the formation of a dielectric layer.

4. The manufacturing method according to claim 1, wherein the electrodes which are formed on the substrate are made of electrodes which are formed in accordance with a thick film method, and the step of carrying out a process for planarization on the dielectric layer comprises planarization through pressing of the electrodes that have been formed in accordance with the thick film method.

5. The manufacturing method according to claim 1, wherein the step of carrying out a process for planarization on the dielectric layer comprises the removal of edge portions of electrodes before the formation of a dielectric layer.

6. The manufacturing method according to claim 5, wherein the step of removing edge portions of electrodes comprises shaving of edges of electrodes in accordance with a sputter etching method after the formation of the electrodes.

7. The manufacturing method according to claim 5, wherein the step of removing edge portions of electrodes comprises shaving of edges of electrodes by means of over etching, by setting the period of time for etching somewhat longer at the time of the formation of the electrodes through wet etching.

8. The manufacturing method according to claim 1, wherein the protective film is formed from MgO in a process for forming a thin film of which the average film thickness is approximately 1 μm.

9. An AC type plasma display panel having a dielectric layer for coating electrodes provided on a substrate and a protective film for coating the dielectric layer, wherein at least one layer, which is a portion of the dielectric layer, is formed in accordance with a vapor phase growth method, and the dielectric layer is approximately flat along the plane of the substrate, irrespectively of the unevenness of the electrodes in the lower layer.

10. The plasma display panel according to claim 9, wherein the dielectric layer is made of an SiO₂ film.
